(19) United States
(12) Patent Application Publication
(10) Pub. No.: US 2024/0014099 A1
(43) Pub. Date: Jan. 11, 2024

(54) INTEGRATED CIRCUIT DEVICE EXPOSED DIE PACKAGE STRUCTURE WITH ADHESIVE

(71) Applicant: Marvell Asia Pte Ltd, Singapore (SG)

(72) Inventor: Choong Kooi Chee, Rocklin, CA (US)

(21) Appl. No.: 18/348,041

(22) Filed: Jul. 6, 2023

Related U.S. Application Data
(60) Provisional application No. 63/358,908, filed on Jul. 7, 2022.

(51) Int. Cl. H01L 23/373; H01L 23/00; H01L 23/31; H01L 23/367

(52) U.S. Cl. CPC H01L 23/3736; H01L 24/16; H01L 23/3128; H01L 23/3142; H01L 23/3675; H01L 2924/3511; H01L 2924/16172; H01L 2224/16225; H01L 2224/16055; H01L 2924/183

(57) ABSTRACT

An integrated circuit (IC) device package includes a structure having a base and walls extending from the base, at least one IC die mounted to the base within the walls, each die having a top surface parallel to the base and having a thickness extending along an axis, perpendicular to the top surface, at most equal to a height of the walls, a thermally conductive heat spreader extending parallel to the base above the die and the walls, and an interface layer including an adhesive layer portion disposed between the walls and the heat spreader to adhere the heat spreader to the walls, and a thermal interface material (TIM) layer portion coplanar with, and laterally displaced from, the adhesive layer portion, the TIM layer portion being disposed in thermally conductive relationship between the heat spreader and each respective die, to dissipate heat from each respective die to the heat spreader.

### CROSS REFERENCE TO RELATED APPLICATION

This disclosure claims the benefit of copending, commonly-assigned U.S. Provisional Patent Application No. 63/358,908, filed Jul. 7, 2022, which is hereby incorporated by reference herein in its entirety.

### FIELD OF USE

This disclosure relates to the packaging of integrated circuit dies. More particularly, the disclosure relates to packages and methods that include interface layer portions in thermal contact with the integrated circuit die and package structure to reduce the likelihood of delamination because of warping of package layers.

### BACKGROUND

The background description provided herein is for the purpose of generally presenting the context of the disclosure. Work of the inventors hereof, to the extent the work is described in this background section, as well as aspects of the description that may not otherwise qualify as prior art at the time of filing, are neither expressly nor impliedly admitted to be prior art against the subject matter of the present disclosure.

An integrated circuit device includes an integrated circuit die on which the device circuits are formed. Typically, the integrated circuit die is mounted on a substrate and is protected by packaging which encloses or surrounds the integrated circuit die. The packaging which encloses or surrounds the integrated circuit die may be a molded package. In an “exposed die” integrated circuit device package, the molded package includes walls which surround the die surface that is attached to the substrate (typically, one of the two largest surfaces of the die), and sides of the die that are perpendicular to the substrate, leaving a remaining side of the integrated circuit die (typically, the other of the two largest surfaces) exposed. A thermally-conductive lid or closure (referred to as a “heat spreader”) may cover the exposed surface of the integrated circuit die to dissipate heat generated by the integrated circuit die when in operation, while protecting the die. The heat spreader may be affixed to the package by a thermally-conductive interface layer to transfer heat from the integrated circuit die to the heat spreader. However, subsequent to affixing the heat spreader to the integrated circuit device package, warping of the package may cause delamination of the interface layer and the heat spreader from the package.

### SUMMARY

In accordance with implementations of the subject matter of this disclosure, an integrated circuit device package includes a package structure having a base and walls extending from the base, at least one integrated circuit die mounted to the package structure base within the walls, each integrated circuit die among the at least one integrated circuit die having a top surface parallel to the base and each integrated circuit die among the at least one integrated circuit die having a thickness extending along an axis, perpendicular to the top surface, at most equal to a height of the walls, a thermally conductive heat spreader extending parallel to the base above the at least one integrated circuit die and above the walls, and an interface layer including an adhesive layer portion disposed between the walls and the heat spreader to adhere the heat spreader to the walls, and a thermal interface material (TIM) layer portion coplanar with, and laterally displaced from, the adhesive layer portion, the TIM layer portion being disposed in thermally conductive relationship between the heat spreader and each respective integrated circuit die from among the at least one integrated circuit die, to dissipate heat from each respective integrated circuit die to the heat spreader.

In a first implementation of such an integrated circuit device package, the package structure may include molded packaging material.

In a second implementation of such an integrated circuit device package, the adhesive layer portion may be thermally conductive.

In a third implementation of such an integrated circuit device package, dies from among the at least one integrated circuit die are arranged in a stack of integrated circuit dies, the stack having a stack thickness, perpendicular to the top surface, at most equal to the height of the walls.

In a fourth implementation of such an integrated circuit device package, the TIM layer portion may include any one of a: (a) polymer TIM, (b) graphite TIM, (c) metal TIM, and (d) liquid metal TIM.

In a fifth implementation of such an integrated circuit device package, the adhesive layer portion may surround the TIM layer portion in the interface layer.

In a sixth implementation of such an integrated circuit device package, the TIM layer portion may be flowable, and the adhesive layer portion may surround the TIM layer portion in the interface layer.

According to a first aspect of that sixth implementation, the adhesive layer portion may form a barrier between the integrated circuit die and the heat spreader, to contain the flowable TIM layer portion.

In a seventh implementation of such an integrated circuit device package, the heat spreader may include a flat lid.

In an eighth implementation of such an integrated circuit device package, the heat spreader may include a forged lid.

In a ninth implementation of such an integrated circuit device package, the heat spreader may include a stamped hat-shaped lid.

In accordance with implementations of the subject matter of this disclosure, a method of packaging at least one integrated circuit die, where each integrated circuit die among the at least one integrated circuit die is mounted to a package structure having a base and walls extending from the base, and where each integrated circuit die from the at least one integrated circuit die has a top surface parallel to the base, and where each integrated circuit die among the at least one integrated circuit die has a thickness, perpendicular to the top surface, at most equal to a height of the walls, includes applying an adhesive layer portion above the walls, applying a thermal interface material (TIM) layer portion coplanar with, and laterally displaced from, the adhesive layer portion, the TIM layer portion being in thermally conductive relationship above each respective integrated circuit die among the at least one integrated circuit die, and placing a thermally conductive heat spreader extending parallel to the base above each of the adhesive layer portion and the TIM layer portion, to adhere the heat spreader to the walls with the adhesive layer portion, and to put the heat spreader in a heat-dissipating relationship with each respective integrated circuit die with the TIM layer portion.

In a first implementation of such a method, applying the TIM layer portion may include applying any one of a (a) polymer TIM, (b) graphite TIM, (c) metal TIM, and (d) liquid metal TIM, coplanar with, and laterally displaced from, the adhesive layer portion, in a thermally conductive relationship between the heat spreader and each respective integrated circuit die from among the at least one integrated circuit die, to dissipate heat from each respective integrated circuit die to the heat spreader.

In a second implementation of such a method, applying the adhesive layer portion above the walls may include applying the adhesive layer portion to surround the TIM layer portion.

In a third implementation of such a method, when the TIM layer portion is flowable, applying the adhesive layer portion to surround the TIM layer portion may include applying the adhesive layer portion to form a barrier between the integrated circuit die and the heat spreader, to contain the TIM layer portion.

A fourth implementation of such a method may further include curing the adhesive layer portion, where the adhesive layer portion binds the walls of the package structure to the heat spreader.

According to a first aspect of that fourth implementation, curing the adhesive layer portion may include heating the adhesive layer portion to a predetermined curing temperature for a predetermined curing duration.

In a fifth implementation of such a method, placing a thermally conductive heat spreader extending parallel to the base above each of the adhesive layer portion and the TIM layer portion may include placing a flat lid above each of the adhesive layer portion and the TIM layer portion.

In a sixth implementation of such a method, placing a thermally conductive heat spreader extending parallel to the base above each of the adhesive layer portion and the TIM layer portion may include placing a forged lid above each of the adhesive layer portion and the TIM layer portion.

In a seventh implementation of such a method, placing a thermally conductive heat spreader extending parallel to the base above each of the adhesive layer portion and the TIM layer portion may include placing a stamped hat-shaped lid above each of the adhesive layer portion and the TIM layer portion.

### BRIEF DESCRIPTION OF THE DRAWINGS

Further features of the disclosure, its nature and various advantages, will be apparent upon consideration of the following detailed description, taken in conjunction with the accompanying drawings, in which like reference characters refer to like parts throughout, and in which:

FIG. 1 is a vertical cross-sectional view of an integrated circuit device package in accordance with implementations of the subject matter of this disclosure;

FIG. 2 shows a progression of stages of fabrication of an integrated circuit device package such as that of FIG. 1 according to some implementations of the subject matter of this disclosure;

FIG. 3 is a vertical cross-sectional view of a three-dimensional (3-D) integrated circuit device package, including stacks of integrated circuit dies rather than individual integrated circuit dies, in accordance with implementations of the subject matter of this disclosure;

FIG. 4 is a vertical cross-sectional view of a 2.5-D integrated circuit device package, with multiple individual integrated circuit dies separated by intermediate walls, in accordance with some implementations of the subject matter of this disclosure;

FIG. 5 is a perspective view of an integrated circuit device package, in accordance with some implementations of the subject matter of this disclosure, prior to the application of a heat spreader;

FIGS. 6 and 7 are cross-sectional views of implementations of an integrated circuit device package similar to FIG. 1 with different types of heat spreaders in accordance with implementations of the subject matter of this disclosure;

FIG. 8 is a flow diagram of a method for fabricating an integrated circuit device package according to some implementations of the subject matter of this disclosure; and

FIG. 9 is a flow diagram of a method for fabricating an integrated circuit device package with a flowable thermal interface material (TIM) according to some implementations of the subject matter of this disclosure.

### DETAILED DESCRIPTION

An “exposed die” integrated circuit device package of the type with which the subject matter of this disclosure may be used has a base or substrate on which at least one integrated circuit die is mounted, with walls—e.g., molded from an epoxy resin—extending from the base and surrounding the integrated circuit die. As noted above, in an exposed-die integrated circuit device package, a thermally-conductive lid or closure (referred to as a “heat spreader”) may be placed over the exposed surface of an integrated circuit die to dissipate heat generated by the integrated circuit die when in operation, while protecting the die. The heat spreader may be affixed to the package by a thermally-conductive interface layer to transfer heat from the integrated circuit die to the heat spreader

However, subsequent to affixing of the heat spreader to the integrated circuit device package, warping of the package may cause delamination of the interface layer and the heat spreader from the package—e.g., during the curing or reflow processes, or during use as a result of heat generated by the integrated circuit device as well as, possibly, mechanical action as the integrated circuit device is moved.

Some integrated circuit device packages of the type with which the subject matter of this disclosure may be used includes a plurality of integrated circuit dies mounted to the base. In such implementations, in addition to walls surrounding the perimeter of the integrated circuit device, there also may be walls between individual integrated circuit devices, or between groups of integrated circuit devices. In this description, and the accompanying drawings, the base or substrate is designated the “bottom” of the package, regardless of its actual orientation, and all directional references in this description are based on that designation.

The walls surrounding, or between, integrated circuit dies of the integrated circuit device package may extend at least as high as top surface of the integrated circuit dies (e.g., the one of the two largest surfaces opposite the surface that which is bonded to the base of the package structure), which remains exposed. In some implementations, the walls of the package structure may extend to the same height as the respective top surfaces of the integrated circuit dies, so that the top surfaces of the walls are flush—i.e., coplanar with—the respective top surfaces of the integrated circuit dies. In other implementations, the walls may extend to a greater height than the top surfaces of the integrated circuit dies. A thermally-conductive lid or closure (referred to as a “heat spreader”) may cover the walls and the exposed surface of the integrated circuit die to dissipate heat generated by the integrated circuit die when in operation, while protecting the die. The heat spreader may be affixed to the package by a thermally-conductive interface layer to transfer heat from the integrated circuit die to the heat spreader.

Conventionally, the interface layer has included only thermal interface materials (TIMs) applied above each of the walls and the integrated circuit dies, to act as both an adhesive to hold the heat spreader in place, and as a heat transfer medium to conduct heat, produced by operation of the integrated circuit dies, to the heat spreader. However, the TIM is designed primarily for its thermal conductivity properties, and the adhesive properties of the TIM may be secondary.

Therefore, if warping occurs—e.g., because of a mismatch between the respective coefficients of thermal expansion (CTEs) of the molded walls and the interface layer, or because of an external mechanical disturbance, the adhesive properties of the TIM may not be sufficient to prevent delamination of the heat spreader from the integrated circuit device package, thereby forming voids in the interface layer where heat cannot be conducted to the heat spreader. In some cases, voids in the interface layer may be focal points for further failures.

Larger integrated circuit device packages, such a ball-grid array (BGA) packages and 2.5-D or 3-D packages, may be more susceptible to warping. A 2.5-D or multi-chip module (MCM) integrated circuit device package may include a plurality of integrated circuit dies mounted onto the package substrate, where the package as a whole, as well as, in some implementations, each integrated circuit die, or group of dies, is surrounded by the walls of the package structure. A 3-D integrated circuit device package may include one or more stacks of integrated circuit dies, where the package as a whole, as well as, in some implementations, each stack of integrated circuit dies, or group of stacks of dies, is surrounded by the walls of the package structure.

In accordance with implementations of the subject matter of this disclosure, the typical TIM interface layer is replaced with an interface layer that includes a TIM portion or portions, and an adhesive portion or portions. The adhesive portions of the interface layer are applied above the walls of the package structure (between the tops of the walls and the heat spreader, while the TIM portions of the interface layer are applied above each of the integrated circuit dies. Unlike the TIM interface layer portions, the adhesive interface layer portions are designed primarily as an adhesive, with better adhesive properties compared to the adhesive properties of the TIM. The adhesive portions provide an improved bonding of the heat spreader to the walls of the package structure once cured, thereby better resisting delamination of the heat spreader if the integrated circuit package warps, as compared to an interface layer that includes TIM alone.

In some implementations, the TIM portions may be any one of (a) a polymer TIM layer portion, (b) a graphite TIM layer portion, (c) a metal TIM layer portion, and (d) a liquid metal TIM layer portion. The adhesive portions may be any suitable integrated circuit device package adhesive which may include, but are not limited to, any one of (a) DOWSIL® EA-8700, (b) DOWSIL® EA-8900, (c) DOWSIL® SE 2304, and (d) DOWSIL® SE 4450, available from Dow Inc. Each of the TIM portions and the adhesive portions may be dispensed onto each respective top surface of the exposed integrated circuit dies and the respective top surface of each wall of the package structure, respectively, by any one of the following: (a) a snowflake-dispensing pattern, (b) a line-dispensing pattern, and (c) a serpentine-dispensing pattern.

In some implementations, thermal conductivity of the adhesive portions may be enhanced in order to allow additional heat dissipation to the heat spreader. For example, the adhesive may be impregnated or infused with particles of a heat conductive material such as, e.g., suitable metal particles.

In some implementations, as described above the TIM portion of the interface layer may be a flowable TIM (e.g., a liquid metal TIM, or a metal TIM that is flowable during reflow operations). In such implementations, the adhesive portions of the interface layer act as a dam to contain the flowable TIM portion. If the TIM portion is flowable during the application of the interface layer (e.g., is a liquid metal TIM), the adhesive portion of the interface layer may be applied first, and then the flowable TIM portion of the interface layer may be applied within the dam formed by the adhesive portion of the interface layer.

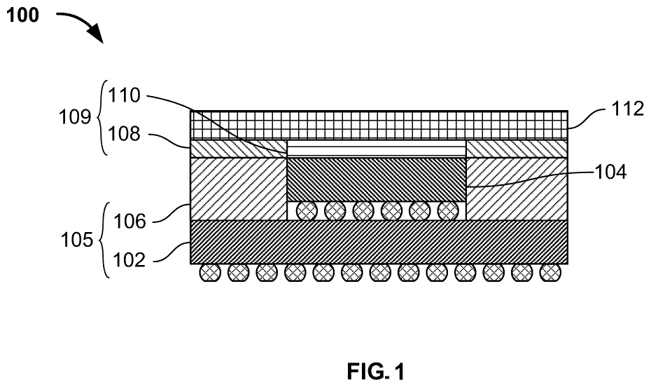

The subject matter of this disclosure may be better understood by reference to FIGS. 1-9.

FIG. 1 illustrates different layers of an integrated circuit device package 100. Integrated circuit device package 100 includes a package structure 105 having a substrate 102 and walls 106. In some implementations, package structure substrate 102 may be formed from a plurality of laminated dielectric layers (e.g., high-density interconnection (HDI) layers). The integrated circuit device package 100 includes an integrated circuit die 104 which is mounted to the substrate 102. In some implementations, the integrated circuit die 104 may be electrically coupled to substrate 102 and bonded by an underfill bonding material.

In implementations of the subject matter of this disclosure, the walls 106 of package structure 105 may surround integrated circuit die 104. In some implementations the walls 106 are formed from a molded packaging material (e.g., molded resin). In other implementations (not shown), the molded packaging material may extend under integrated circuit die 104, between integrated circuit die 104 and substrate 102. Each integrated circuit die 104 has a thickness, measured along a line perpendicular to the substrate 102, that is at most equal to a height of walls 106.

An interface layer 109 including adhesive portion or portions 108 and thermal interface material (TIM) portion or portions 110 are applied to the top surfaces of walls 106 and the exposed top surfaces of the integrated circuit die 104. Specifically, adhesive portion or portions 108 are applied to the top surfaces of walls 106, while TIM portion or portions 110 are applied to the exposed top surfaces of the integrated circuit die 104. A thermally-conductive heat spreader 112 is placed above (in the orientation of the drawing) each of the interface layer 109 that includes adhesive portions 108 and TIM portions 110. Adhesive layer portions 108 adhere heat spreader 112 to walls 106. TIM portions 110 are applied in thermally conductive relationship between heat spreader 112 and integrated circuit die 104, to conduct heat produced during operation of integrated circuit die 104 to heat spreader 112, which functions as a heat sink. Heat spreader 112 may also function as a lid to protect integrated circuit die 104 from mechanical damage.

As noted above, integrated circuit device package 100 may be susceptible to warping, which could cause heat spreader 112 to separate from integrated circuit device package 100, reducing its heat-sinking ability and possibly allowing integrated circuit device 104 to overheat and fail. By replacing TIM 110 with adhesive 108 above walls 106, adhesion of heat spreader 112 to integrated circuit device package 100 is improved, reducing the likelihood of separation of heat spreader 112 due to warping. Moreover, the improved adhesion of heat spreader 112 to integrated circuit device package 100 may provide increased mechanical stiffness to help resist warping of the integrated circuit device package 100.

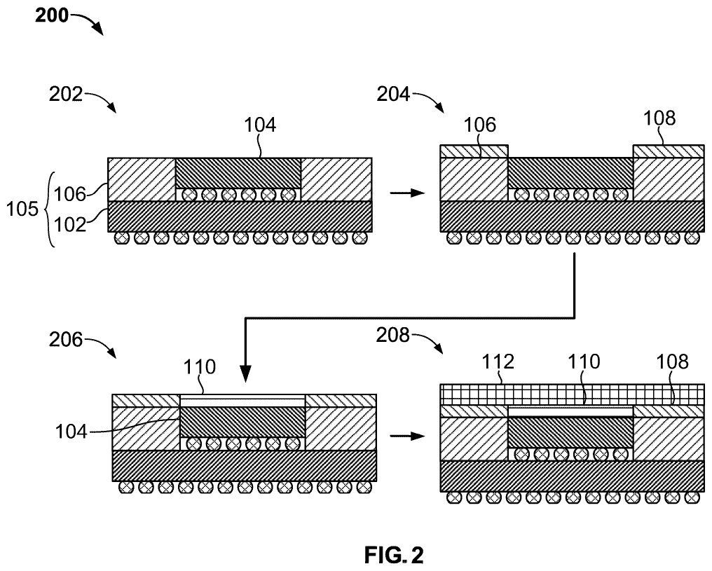

An implementation 200 of a method for fabricating an integrated circuit device package 100 in accordance with the subject matter of this disclosure is illustrated in FIG. 2. At 202, one or more (one shown) integrated circuit dies 104 are disposed above base or substrate 102 of package structure 105 with walls 106 of package structure 105—molded, e.g., from an epoxy resin—surrounding integrated circuit die 104. The top surface of integrated circuit die 104 remains exposed. Adhesive portions 108 are then applied above walls 106 of package structure 105 at 204. TIM portions 110 are then applied above each integrated circuit die 104, at 206. TIM portions 110 and adhesive portions 108 are part of one interface layer 109, being coplanar with, but laterally separated from, each other. At 208, a heat spreader 112 is placed above the adhesive portions 108 and TIM portions 110 of the interface layer 109. While adhesive portions 108 is shown as being applied before TIM portions 110, unless TIM portions 110 are flowable during application (e.g., are a liquid metal TIM), then it is also possible for TIM portions 110 to be applied before adhesive portions 108, or for adhesive portions 108 and TIM portions 110 to be applied simultaneously.

TIM portions 110 are disposed in thermally conductive relationship between integrated circuit die 104 and the heat spreader 112, allowing heat from operation of integrated circuit die 104 to dissipate through TIM portions 110 to heat spreader 112.

After assembly of integrated circuit device package 100 (e.g., as shown in FIG. 2), the interface layer 109 (e.g., adhesive portions 108 and TIM portions 110) may be cured to bond heat spreader 112 to package structure walls 106. Depending on the nature of adhesive portions 108, curing may be performed for a predetermined curing duration using heat, a chemical reaction or a suitable wavelength of light, such as, e.g., ultraviolet light, which may be delivered by a laser or other suitable source. In implementations in which TIM portion 110 is a metal TIM, reflow of the TIM may be performed to bond heat spreader 112 to integrated circuit die 104.

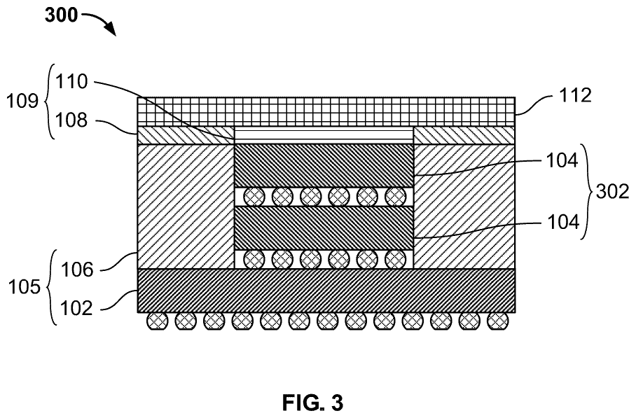

FIG. 3 illustrates the structure of a three-dimensional (3-D) integrated circuit device package 300, similar to that of FIG. 1, but with at least one stack 302 of at least two integrated circuit dies 104 in place of an individual integrated circuit die 104. In some implementations, a stack 302 may include a third integrated circuit die (not shown). The walls 106 of a 3-D integrated circuit device package may be molded (e.g., from an epoxy resin), and in any case have a top surface at least as high as the top surface of a top-most integrated circuit die 104 in stack 302. As previously disclosed, adhesive layer portions 108 of the interface layer 109 are applied above walls 106, and TIM portions 110 of the interface layer 109 are affixed above the top-most integrated circuit die 104 in stack 302. A heat spreader 112 is placed above package 300, in contact with each of the adhesive portions 108 and the TIM portions 110 of the interface layer 109.

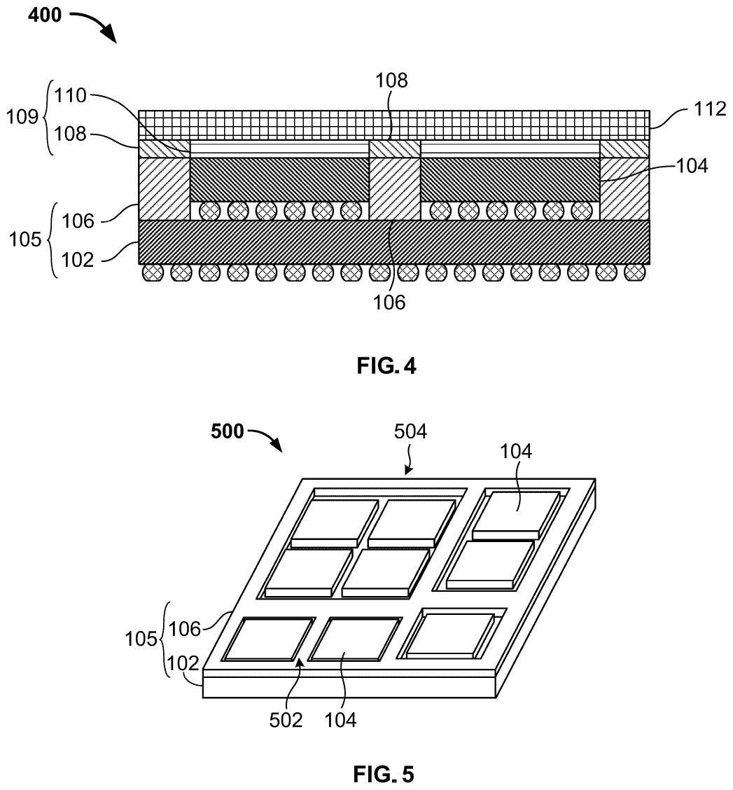

FIG. 4 illustrates a 2.5-D/Multi-Chip Module (MCM) integrated circuit device package 400, similar to that of FIG. 1, but with multiple integrated circuit dies 104 arranged laterally and separated by intermediate walls 106, in accordance with implementations of the subject matter of this disclosure. The 2.5-D/MCM integrated circuit device package 400 includes a plurality of integrated circuit dies 104 disposed on the base or substrate 102. As seen, in this implementation, not only is there a wall 106 around the perimeter of package 400, but there also is a wall 106 between dies 104. As previously disclosed, adhesive portions 108 of interface layer 109 are applied above walls 106, including walls 106 between integrated circuit dies 104. TIM portions 110 of interface layer 109 are affixed above each respective top surface of each respective integrated circuit die 104, between adhesive portions 108. Heat spreader 112 is disposed above adhesive portions 108 and TIM portions 110 of interface layer 109 to adhere the heat spreader 112 to integrated circuit device package 400.

FIG. 5 shows a 2.5-D/MCM integrated circuit device package 500 with exposed integrated circuit dies 104 disposed on base or substrate 102 of package structure 105, in accordance with some implementations of the subject matter of this disclosure. As previously disclosed, walls 106 of package structure 105 may surround integrated circuit dies 104. The 2.5-D/MCM integrated circuit device package 500 includes some integrated circuit dies 104 that are individually surrounded by walls 106, such as, e.g., those integrated circuit dies in area 502 of integrated circuit device package 500, and other integrated circuit dies 104 that are grouped together within walls 106, such as, e.g., those integrated circuit dies in area 504 of integrated circuit device package 500. Each integrated circuit die 104 has a thickness, measured perpendicular to the base 102, that is at most equal to a height of walls 106. That is, walls 106 surrounding, or between, integrated circuit dies 104 may extend at least as high as the top surfaces of integrated circuit dies 104, which remain exposed. Although not shown in this drawing, as previously disclosed, and as shown in connection with other implementations described above, adhesive portions 108 of interface layer 109 are applied above walls 106, including walls 106 between, or surrounding groups of, integrated circuit dies 104. TIM portions 110 of interface layer 109 are affixed above each respective top surface of each respective integrated circuit die 104, between adhesive portions 108. Heat spreader 112 is disposed above adhesive portions 108 and TIM portions 110 of interface layer 109 to adhere the heat spreader 112 to integrated circuit device package 500.

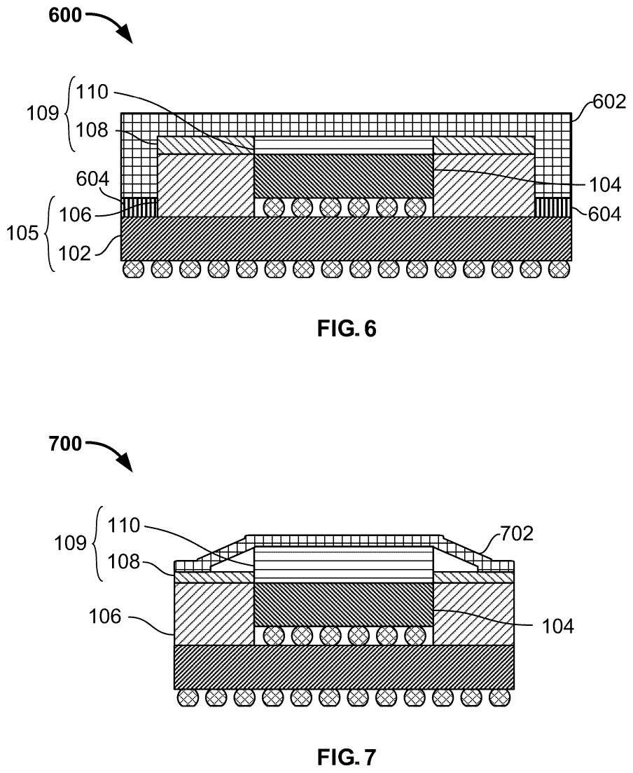

FIGS. 6 and 7 are vertical cross-sectional views of implementations of an integrated circuit device package similar to FIG. 1, but with different types of heat spreaders, as compared to the flat-lid-type heat spreader 112, in accordance with implementations of the subject matter of this disclosure. For example, as depicted in FIG. 6, the integrated circuit device package 600 includes a forged-lid-type heat spreader 602 disposed above interface layer 109 that includes adhesive portions 108 and TIM portions 110. Optionally, forged-lid-type heat spreader 602 may be additionally adhered to base 102 of package structure 105 by an adhesive or bonding agent at 604. In some such implementations, adhesive 604 may be the same adhesive as adhesive portions 108. FIG. 7 shows another implementation, in which integrated circuit device package 700 includes a stamped hat-shaped heat spreader 702.

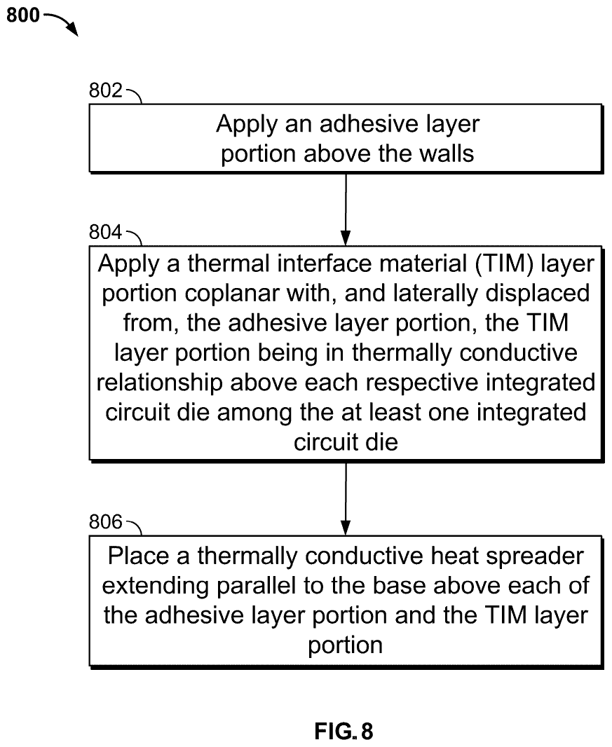

A method 800 in accordance with implementations of the subject matter of this disclosure is diagrammed in FIG. 8. Method 800 begins at 802, where an adhesive layer portion is applied above the walls. At 804, a thermal interface material (TIM) layer portion is applied coplanar with, and laterally displaced from, the adhesive layer portion, the TIM layer portion being in thermally conductive relationship above each respective integrated circuit die among the at least one integrated circuit die. At 806, a thermally conductive heat spreader extending parallel to the base is placed above each of the adhesive layer portion and the TIM layer portion.

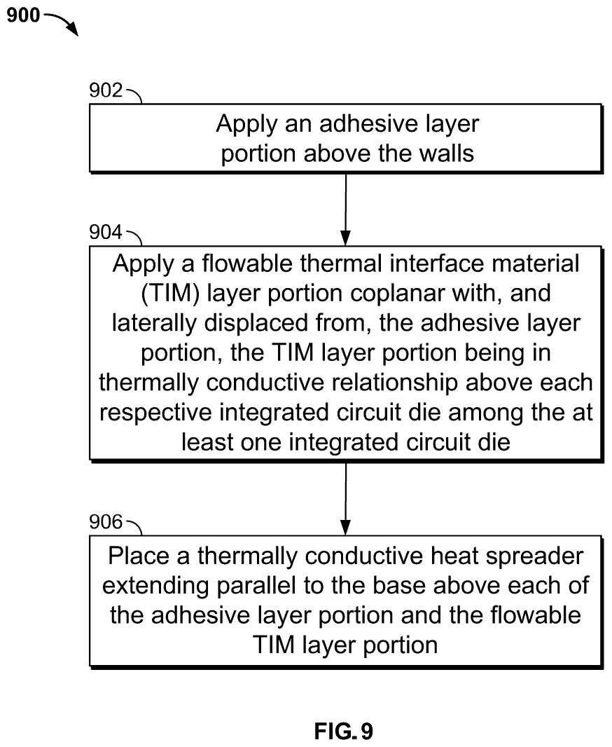

A method 900 in accordance with implementations of the subject matter of this disclosure is diagrammed in FIG. 9. Method 900 begins at 902, where an adhesive layer portion is applied above the walls. At 904, a flowable thermal interface material (TIM) layer portion is applied coplanar with, and laterally displaced from, the adhesive layer portion, the flowable TIM layer portion being in thermally conductive relationship above each respective integrated circuit die among the at least one integrated circuit die. At 906, a thermally conductive heat spreader extending parallel to the base is placed above each of the adhesive layer portion and the flowable TIM layer portion.

In alternative implementations (not shown in FIGS. 8 and 9), each integrated circuit die among the at least one integrated circuit die may be mounted to the base of the package structure before the walls of the package structure are disposed around each integrated circuit die. The walls of the package structure are formed with a height, extending from the base of the package structure, where the thickness of the integrated circuit die is at most equal to the height of the walls of the package structure.

Thus it is seen that an integrated circuit device package that provides heat dissipation and reduces the likelihood of delamination of package layers due to warping, has been provided.

As used herein and in the claims which follow, the construction “one of A and B” shall mean “A or B.”

It is noted that the foregoing is only illustrative of the principles of the invention, and that the invention can be practiced by other than the described embodiments, which are presented for purposes of illustration and not of limitation, and the present invention is limited only by the claims which follow.

What is claimed is:

1. An integrated circuit device package comprising:
a package structure having a base and walls extending from the base;
at least one integrated circuit die mounted to the package structure base within the walls, each integrated circuit die among the at least one integrated circuit die having a top surface parallel to the base and each integrated circuit die among the at least one integrated circuit die having a thickness extending along an axis, perpendicular to the top surface, at most equal to a height of the walls;
a thermally conductive heat spreader extending parallel to the base above the at least one integrated circuit die and above the walls; and
an interface layer comprising:
an adhesive layer portion disposed between the walls and the heat spreader to adhere the heat spreader to the walls; and
a thermal interface material (TIM) layer portion coplanar with, and laterally displaced from, the adhesive layer portion, the TIM layer portion being disposed in thermally conductive relationship between the heat spreader and each respective integrated circuit die from among the at least one integrated circuit die, to dissipate heat from each respective integrated circuit die to the heat spreader.

2. The integrated circuit device package of claim 1, wherein the package structure comprises molded packaging material.

3. The integrated circuit device package of claim 1, wherein the adhesive layer portion is thermally conductive.

4. The integrated circuit device package of claim 1, wherein dies from among the at least one integrated circuit die are arranged in a stack of integrated circuit dies, the stack having a stack thickness, perpendicular to the top surface, at most equal to the height of the walls.

5. The integrated circuit device package of claim 1, wherein the TIM layer portion comprises any one of a: (a) polymer TIM, (b) graphite TIM, (c) metal TIM, and (d) liquid metal TIM.

6. The integrated circuit device package of claim 1, wherein the adhesive layer portion surrounds the TIM layer portion in the interface layer.

7. The integrated circuit device package of claim 1 wherein:
the TIM layer portion is flowable; and
the adhesive layer portion surrounds the TIM layer portion in the interface layer.

8. The integrated circuit device package of claim 7 wherein the adhesive layer portion forms a barrier between the integrated circuit die and the heat spreader, to contain the flowable TIM layer portion.

9. The integrated circuit device package of claim 1, wherein the heat spreader comprises a flat lid.

10. The integrated circuit device package of claim 1, wherein the heat spreader comprises a forged lid.

11. The integrated circuit device package of claim 1, wherein the heat spreader comprises a stamped hat-shaped lid.

12. A method of packaging at least one integrated circuit die, each integrated circuit die among the at least one integrated circuit die being mounted to a package structure having a base and walls extending from the base, each integrated circuit die from the at least one integrated circuit die having a top surface parallel to the base, and each integrated circuit die among the at least one integrated circuit die having a thickness, perpendicular to the top surface, at most equal to a height of the walls, the method comprising:
applying an adhesive layer portion above the walls;
applying a thermal interface material (TIM) layer portion coplanar with, and laterally displaced from, the adhesive layer portion, the TIM layer portion being in thermally conductive relationship above each respective integrated circuit die among the at least one integrated circuit die; and
placing a thermally conductive heat spreader extending parallel to the base above each of the adhesive layer portion and the TIM layer portion, to adhere the heat spreader to the walls with the adhesive layer portion, and to put the heat spreader in a heat-dissipating relationship with each respective integrated circuit die with the TIM layer portion.

13. The method according to claim 12 of packaging at least one integrated circuit die, wherein applying the TIM layer portion comprises applying any one of a (a) polymer TIM, (b) graphite TIM, (c) metal TIM, and (d) liquid metal TIM, coplanar with, and laterally displaced from, the adhesive layer portion, in a thermally conductive relationship between the heat spreader and each respective integrated circuit die from among the at least one integrated circuit die, to dissipate heat from each respective integrated circuit die to the heat spreader.

14. The method according to claim 12 of packaging at least one integrated circuit die, wherein applying the adhesive layer portion above the walls comprises applying the adhesive layer portion to surround the TIM layer portion.

15. The method according to claim 14 of packaging at least one integrated circuit die, wherein, when the TIM layer portion is flowable, applying the adhesive layer portion to surround the TIM layer portion comprises applying the adhesive layer portion to form a barrier between the integrated circuit die and the heat spreader, to contain the TIM layer portion.

16. The method according to claim 12 of packaging at least one integrated circuit die, further comprising curing the adhesive layer portion, wherein the adhesive layer portion binds the walls of the package structure to the heat spreader.

17. The method according to claim 16 of packaging at least one integrated circuit die, wherein curing the adhesive layer portion comprises heating the adhesive layer portion to a predetermined curing temperature for a predetermined curing duration.

18. The method according to claim 12 of packaging at least one integrated circuit die, wherein placing a thermally conductive heat spreader extending parallel to the base above each of the adhesive layer portion and the TIM layer portion comprises placing a flat lid above each of the adhesive layer portion and the TIM layer portion.

19. The method according to claim 12 of packaging at least one integrated circuit die, wherein placing a thermally conductive heat spreader extending parallel to the base above each of the adhesive layer portion and the TIM layer portion comprises placing a forged lid above each of the adhesive layer portion and the TIM layer portion.

20. The method according to claim 12 of packaging at least one integrated circuit die, wherein placing a thermally conductive heat spreader extending parallel to the base above each of the adhesive layer portion and the TIM layer portion comprises placing a stamped hat-shaped lid above each of the adhesive layer portion and the TIM layer portion.
